(19) United States
(12) Patent Application Publication
(10) Pub. No.: US 2024/0395986 A1
(43) Pub. Date: Nov. 28, 2024

(54) LIGHT-EMITTING ELEMENT, MANUFACTURING METHOD THEREOF, AND PACKAGE STRUCTURE COMPRISING THE SAME

(71) Applicant: Lextar Electronics Corporation, Hsinchu City (TW)

(72) Inventors: Shiou-Yi KUO, Hsinchu City (TW); Jian-Chin LIANG, Hsinchu City (TW); Cheng-Hsien LI, Hsinchu City (TW); Kai Hung CHENG, Hsinchu City (TW)

(21) Appl. No.: 18/669,141

(22) Filed: May 20, 2024

(30) Foreign Application Priority Data
May 23, 2023 (TW) 112119044

(51) Int. Cl. H01L 33/58; H01L 25/075; H01L 33/10; H01L 33/38

(52) U.S. Cl. CPC H01L 33/58; H01L 25/0753; H01L 33/10; H01L 33/382; H01L 2933/0058

(57) ABSTRACT

A light-emitting element, a manufacturing method thereof, and a package structure are provided. The light-emitting element includes a first semiconductor layer, an active layer disposed on the first semiconductor layer, a second semiconductor layer disposed on the active layer, and a convex lens structure disposed on the second semiconductor layer. The convex lens structure includes a plurality of microlenses. The microlenses and the second semiconductor layer are integrally formed and have the same material. The radius of curvature of one of the microlenses is 0.2 μm to 5.0 μm, and the light-emission angle of the light-emitting element is 100° to 110°.

### CROSS REFERENCE TO RELATED APPLICATIONS

This application claims priority of Taiwan Patent Application No. 112119044, filed on May 23, 2023, and the content of the entirety of which is incorporated by reference herein.

### BACKGROUND

### Field of the Disclosure

The present disclosure relates to semiconductor technology, and, in particular, to a light-emitting element and a manufacturing method thereof.

### Description of the Related Art

With the high development of electronic devices, each element in an electronic device is gradually being scaled down. The reduction in size of light-emitting diode (LED) units, for example, greatly increases the difficulty of the manufacturing process, leading to problems such as a decrease in yield. Although the current micro LEDs have generally been adequate for their intended use, they have not been entirely satisfactory in all respects. Therefore, there are still some issues to be addressed regarding micro LEDs.

### SUMMARY

An embodiment of the present disclosure provides a light-emitting element including a first semiconductor layer, an active layer disposed on the first semiconductor layer, a second semiconductor layer disposed on the active layer, and a convex lens structure disposed on the second semiconductor layer. The convex lens structure includes a plurality of microlenses. The microlenses and the second semiconductor layer are integrally formed and have the same material. A radius of curvature of one of the microlenses is 0.2 μm to 5.0 μm, and a light-emission angle of the light-emitting element is 100° to 110°.

An embodiment of the present disclosure further provides a package structure including: a first metal pad and a plurality of second metal pads, the second metal pads are separated from each other, and the first metal pad is separated from each of the second metal pads; a plurality of light-emitting elements disposed on the first metal pad and the second metal pads, each of the light-emitting elements has a light-emitting surface with a convex lens structure; and an encapsulation layer encapsulating the light-emitting elements. The first metal pad is electrically connected to at least two of the light-emitting elements, and the second metal pads are electrically connected to the corresponding one of the light-emitting elements respectively.

An embodiment of the present disclosure provides a manufacturing method of a light-emitting element. The method includes: providing a substrate having a plurality of light-emitting diode chips disposed thereon, each of the light-emitting diode chips comprises a first semiconductor layer, an active layer, and a second semiconductor layer stacked in sequence while the second semiconductor layer positioned between the active layer and the substrate; removing the substrate from the light-emitting diode chips to form a plurality of uneven surfaces of the second semiconductor layers; removing the uneven surfaces of the second semiconductor layers to form a plurality of flat surfaces; and patterning the flat surfaces of the second semiconductor layers to form convex lens structures.

### BRIEF DESCRIPTION OF THE DRAWINGS

The present disclosure can be more fully understood by reading the subsequent detailed description and examples with references made to the accompanying drawings. It is noted that, in accordance with the standard practice in the industry, various features are not drawn to scale and are merely used for illustration. In fact, the dimensions of the various elements may be arbitrarily increased or reduced to clearly represent the features of the embodiments of the present disclosure. In the accompanying drawings:

FIG. 1 shows a cross-sectional view of a light-emitting element in accordance with some embodiments of the present disclosure.

FIG. 2 shows a perspective view of a light-emitting element in accordance with some embodiments of the present disclosure.

FIG. 3 shows a top view of a light-emitting element in accordance with some embodiments of the present disclosure.

FIG. 4 to FIG. 9 show cross-sectional views of different stages of a method forming a light-emitting element in accordance with some embodiments of the present disclosure;

FIG. 10 shows a top view of a package structure in accordance with some embodiments of the present disclosure; and

FIG. 11 shows a cross-sectional view of a package structure taken along line B-B′ of FIG. 10 in accordance with some embodiments of the present disclosure.

### DETAILED DESCRIPTION OF THE DISCLOSURE

The following disclosure provides many different embodiments, or examples, for implementing different components of the provided subject matter. Specific examples of components and arrangements are described below to simplify the illustration of the present disclosure. These are, of course, merely examples and are not intended to limit the present disclosure. For example, the formation of a first component over or on a second component in the description that follows may include embodiments in which the first and second components are formed in direct contact, and may also include embodiments in which additional components may be formed between the first and second components, such that the first and second components may not be in direct contact. In addition, the present disclosure may repeat reference numerals and/or letters in the various examples. This repetition is for the purpose of simplicity and clarity and does not indicate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The component may be otherwise oriented (rotated 90 degrees or at other orientations) and the spatially relative descriptors used herein may likewise be interpreted accordingly.

In the present disclosure, the terms “about”, “substantially”, or the like, represents within 10%, 5%, 3%, 2%, 1%, or 0.5%, of a given value or range. The given value herein is an approximate value, that is, even though there is no specific description of “about” or “substantially”, the given value implicitly includes the meaning of “about” or “substantially”.

Forming method of some embodiments of the present disclosure are described. In these embodiments, additional operations can be provided before, during, and/or after the stages described. Some of the stages that are described can be replaced or eliminated for different embodiments. Additional components can be added to the structure. Some of the components described below can be replaced or eliminated for different embodiments. Although some embodiments are discussed with operations performed in a particular order, these operations may be performed in another logical order.

Unless defined otherwise, all terms (including technical and scientific terms) used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the disclosure and the background or the context of the disclosure, and should not be interpreted in an idealized or overly formal manner unless so defined.

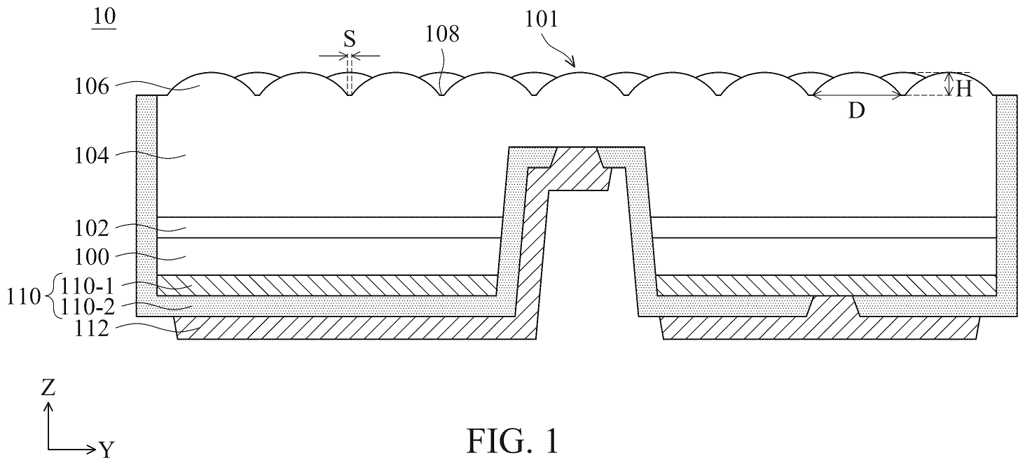

First, FIG. 1 to FIG. 3 respectively show a cross-sectional view, a perspective view and a top view of a light-emitting element 10 in accordance with some embodiments of the present disclosure. As shown in FIG. 1, the light-emitting element 10 has a first semiconductor layer 100, an active layer 102, and a second semiconductor layer 104. In some embodiments, the material of the first semiconductor layer 100, the active layer 102, and the second semiconductor layer 104 may be gallium nitride (GaN), gallium arsenide (GaAs), indium phosphide (InP), aluminum gallium nitride (AlGaN), indium gallium nitride (InGaN), gallium indium phosphide (GaInP), aluminum gallium arsenide (AlGaAs), or aluminum gallium indium phosphide (AlGaInP), or the like. In some embodiments, the first semiconductor layer 100 and the second semiconductor layer 104 may have different conductivity types. For example, the first semiconductor layer 100 may be a p-type semiconductor layer, and the second semiconductor layer 104 may be an n-type semiconductor layer. Alternatively, the first semiconductor layer 100 may be an n-type semiconductor layer, and the second semiconductor layer 104 may be a p-type semiconductor layer.

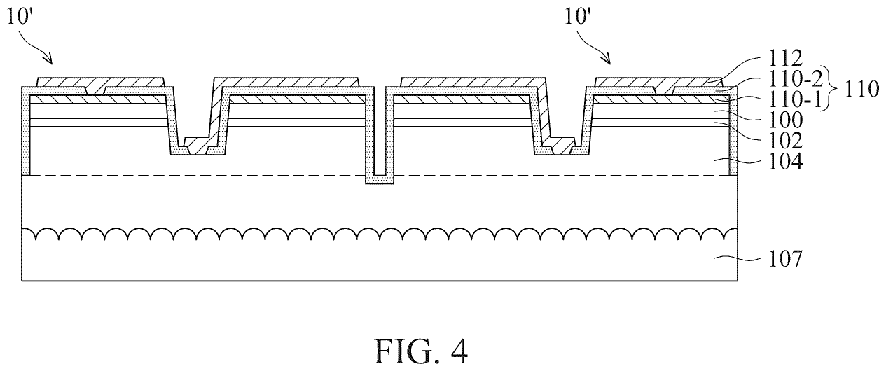

As shown in FIG. 1, a convex lens structure including a plurality of microlenses 106 is disposed on the second semiconductor layer 104 of the light-emitting element 10. In some embodiment, the microlenses 106 can converge the light emitted from the active layer 102 to reduce the light-emission angle of the light emitting from the light-emitting surface 101 of the light-emitting element 10. It should be noted that in the present disclosure, the microlenses 106 and the second semiconductor layer 104 are integrally formed and have the same material. In other words, there is no interface between the microlenses 106 and the second semiconductor layer 104. By making the microlenses 106 and the second semiconductor layer 104 integrally formed with the same material, when the light generated from the active layer 102 enters the microlenses 106, the refraction due to different media that significantly affects the light-emission angle may be avoided. The formation of the microlenses 106 will be described below in the paragraphs related to FIG. 4 to FIG. 9. Moreover, as shown in FIG. 1, the second semiconductor layer 104 has flat regions 108 between the microlenses 106, and the flat regions 108 and the microlenses 106 collectively form a light-emitting surface 101 of the light-emitting element 10. Accordingly, in the present disclosure, the emission light of the light-emitting element 10 can be converged by the microlenses 106 formed on the second semiconductor layer 104, thereby narrowing the light-emission angle of the light-emitting element 10. In some embodiments, the light-emission angle of the light-emitting element 10 may be less than about 120 degrees, for example, about 110 degrees to 120 degrees, or about 100 degrees to about 110 degrees. Accordingly, the present disclosure can further reduce the light-emission angle by about 20%. It should be noted that the abovementioned light-emission angle refers to the light-emission angle of the whole light-emitting element 10, i.e., the combination of the light-emission angle of the microlenses 106, rather than the light-emission angle of a single microlens 106. In some embodiments, a spacing S between the microlenses 106 may be less than about 2 μm, for example, about 1 μm. If the spacing S is greater than 2 μm, the arrangement of the microlenses 106 may be too loose, and more light emitted from the flat region 108 instead of the microlenses 106, so that decreases the light converging effect of the microlenses 106. It should be appreciated that the microlenses 106 may also be closely connected without the flat region 108 (i.e., the spacing S is 0).

It should be noted that, as long as the abovementioned effect of converging light and reducing the light-emission angle can be achieved, the present disclosure is not particularly limited to the size, material and/or arrangement of the microlenses 106, and each of the microlenses 106 on the same light-emitting element 10 may have different size and/or arrangement. In some embodiments, the diameter D of the microlens 106 may be about 1 μm to about 4 μm, about 1.5 μm to about 3.5 μm, or about 2 μm to about 3 μm. In some embodiments, the height H of the microlens 106 may be about 0.5 μm to about 5.0 μm, about 1.5 μm to about 4 μm, or about 2.5 μm to about 3 μm. In some embodiments, the radius of curvature of the microlens 106 may be about 0.2 μm to about 5 μm, about 0.5 μm to about 4.5 μm, or about 1.5 μm to about 3.5 μm. In some embodiments, the K-curvature of the microlens 106 may be about 0.2 μm to about 5 μm, about 0.235 μm to about 2 μm, or about 0.286 μm to about 0.67 μm. If the diameter, height, radius of curvature, or K-curvature of the microlens 106 is out of the abovementioned ranges, the microlens 106 may not narrow the light-emission angle effectively or even cannot converge light. In some embodiments, the arrangement of the microlenses 106 is two-dimensional hexagonal close-packed (2D-HCP). That is, each microlens 106 is surrounded by other six microlenses 106 on the light-emitting surface 101 to minimize the spacing S between the microlenses 106.

Still referring to FIG. 1, in some embodiments, the light-emitting element 10 may include a reflection layer 110. The reflection layer 110 has a high reflectivity for the light from the active layer 102, such as greater than 90%, to increase the external quantum efficiency (EQE) of the light-emitting element 10.

In some embodiments, the reflection layer 110 may comprise an electrode layer 110-1 and an insulating layer 110-2. The electrode layer 110-1 may include a transparent conductive material or a metal material. For example, the transparent conductive material may comprise indium tin oxide (ITO), indium zinc oxide (IZO), aluminum zinc oxide (AZO), or other suitable transparent conductive material, and the metal material may comprise titanium (Ti), nickel (Ni), aluminum (Al), gold (Au), platinum (Pt), chromium (Cr), silver (Ag), copper (Cu), other suitable metals or the combinations. The insulating layer 110-2 may include silicon oxide (SiO₂), titanium oxide (TiO₂), tantalum oxide (Ta₂O₅), aluminum oxide (Al₂O₃), silicon nitride (Si₃N₄), other suitable material, or the combinations. In some embodiments, the insulating layer 110-2 may include a periodic structure comprising a distributed Bragg reflector (DBR) including two layers with different refractive index, such as SiO₂ and TiO₂, alternately arranged, or a dielectric waveguide having a characteristic of periodically changing its effective refractive index.

In one embodiment, the reflection layer 110 is composed of the electrode layer 110-1 with the transparent conductive material and the insulating layer 110-2 being the DBR. In this embodiment, the electrode layer 110-1 forms an ohmic contact with the first semiconductor layer 100, and the insulating layer 110-2 reflects the light emitted from the active layer 102 toward the light-emitting surface 101. In another embodiment, the reflection layer 110 may be composed of the electrode layer 110-1 with the metal material and the insulating layer 110-2 without periodic structure. In this embodiment, the electrode layer 110-1 forms an ohmic contact with the first semiconductor layer 100 and reflects the light emitted from the active layer 102 toward the light-emitting surface 101. In yet another embodiment, the reflection layer 110 may be composed of the electrode layer 110-1 with the metal material and the insulating layer 110-2 being the DBR. In this embodiment, the electrode layer 110-1 and the insulating layer 110-2 cooperate to reflect the light emitted from the active layer 102 toward the light-emitting surface 101. As long as the abovementioned effect of increasing the external quantum efficiency can be achieved, the present disclosure is not particularly limited to the material of the reflection layer 110. In some embodiments, a part of the reflection layer 110 which is vertically overlapped with the first semiconductor layer 100 has a thickness, i.e., the combination of a thickness of the electrode layer 110-1 and a thickness of the insulating layer 110-2. The range of the thickness of the part of the reflection layer 110 is about 0.1 μm to 4 μm, for example, about 0.5 μm.

Still referring to FIG. 1, the light-emitting element 10 may include a pair of electrodes 112 for providing electrical connection of the light-emitting element 10. In some embodiments, one of the electrodes 112 may be electrically connected to the first semiconductor layer 100, and another one of the electrodes 112 may be electrically connected to the second semiconductor layer 104. In some embodiments, the material of the electrode 112 may include metal. For example, the metal may comprise chromium (Cr), copper (Cu), aluminum (Al), indium (In), tin (Sn), gold (Au), platinum (Pt), zinc (Zn), silver (Ag), titanium (Ti), nickel (Ni), alloys thereof, or the combination thereof, but not limited thereto. In some embodiments, the electrode 112 is formed of a stack of chromium/platinum/gold (Cr/Pt/Au).

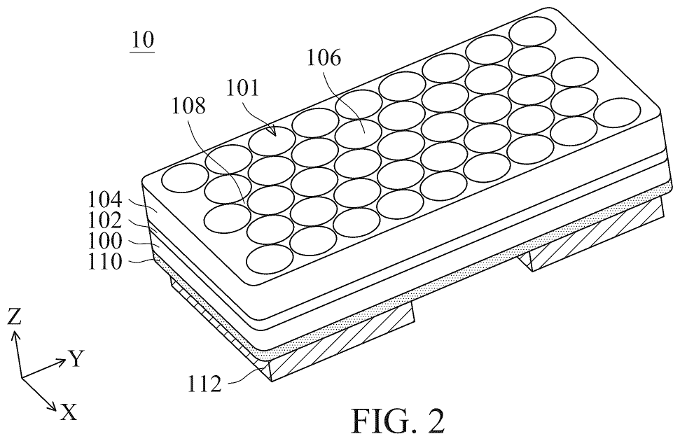

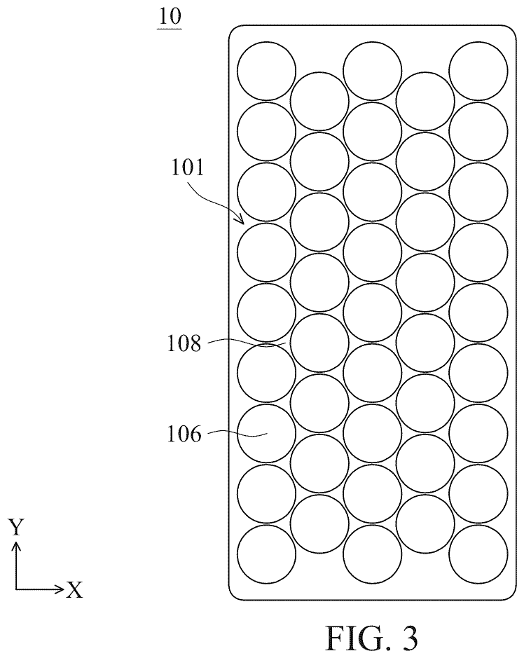

Next, referring to FIG. 2 and FIG. 3, the light-emitting surface 101 of the light-emitting element 10 is composed of a plurality of microlenses 106 and flat regions 108 between the microlenses 106. In this embodiment, all microlenses 106 have the same size and are arranged in a manner of hexagonal close-packed (HCP). It should be noted that although FIG. 2 shows the reflection layer 110 and the electrodes 112 as being only under the light-emitting element 10, the reflection layer 110 and the electrode 112 may have structures similar to those in FIG. 1. That is, the reflection layer 110 may extend upwards to cover the sidewalls of the light-emitting element 10, and the electrodes 112 may also extend upwards to electrically contact the first semiconductor layer 100 and the second semiconductor layer 104 respectively, which is omitted in the drawing for the sake of brevity.

FIG. 4 to FIG. 9 show cross-sectional views of manufacturing the light-emitting element 10 in different stages in accordance with some embodiments. First, referring to FIG. 4, a native substrate 107 with a plurality of light-emitting diode chips 10′ (LED chips) disposed thereon is provided, and each of the LED chips 10′ includes a first semiconductor layer 100, an active layer 102, and a second semiconductor layer 104 stacked in sequence, the second semiconductor layer 104 is disposed between the first semiconductor layer 100 and the native substrate 107. The first semiconductor layer 100, the active layer 102, and the second semiconductor layer 104 may be or formed with any suitable materials discussed above, and may be formed by any suitable epitaxial growth process, for example, metal-organic chemical vapor deposition (MOCVD), hydride vapor phase epitaxy (HVPE), molecular beam epitaxy (MBE), liquid-phase epitaxy (LPE), vapor phase epitaxy (VPE), combinations thereof, or the like. In some embodiments, the material of the native substrate 107 may be sapphire, and the material of the first semiconductor layer 100 and the second semiconductor layer 104 may be gallium nitride (GaN). In some embodiment, the second semiconductor layers 104 of the LED chips 10′ may be connected to each other. In other words, the LED chips 10′ on the native substrate 107 are connected to each other by the connecting second semiconductor layers 104. Moreover, as shown in FIG. 4, each of the LED chips 10′ further comprise the reflection layer 110 and the pair of the electrodes 112 sequentially formed on the first semiconductor layer 100. Specifically, the reflection layer 110 comprises the electrode layer 110-1 formed on the first semiconductor layer 100 and the insulating layer 110-2 covers the electrode layer 110-1, and the pair of the electrodes 112 cover the insulating layer 110-2. In some embodiments, the pair of the electrodes 112 are electrically separated from each other by the insulating layer 110-2 and penetrate the insulating layer 110-2 to electrically connect to the electrode layer 110-1 and the second semiconductor layer 104 respectively. The materials of the reflection layer 110 and the electrodes 112 may be or formed with any suitable materials discussed above, and will not repeat here.

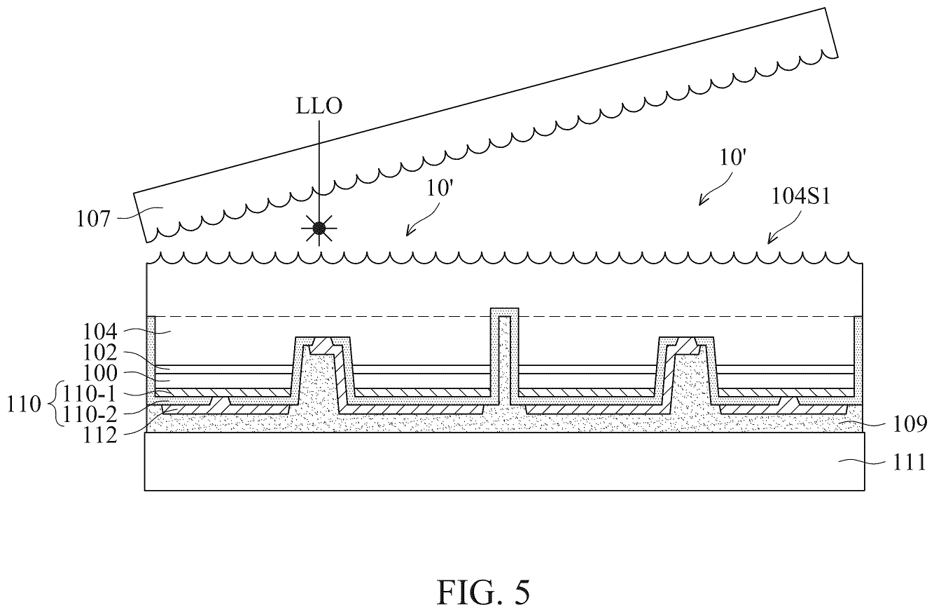

Next, referring to FIG. 5, the LED chips 10′ may be firstly flipped and bonded to the temporary substrate 111 through the bonding layer 109, then, a laser lift-off (LLO) process may be performed to remove the native substrate 107. It should be noted that as long as the temporary substrate 111 and the bonding layer 109 can perform their functions of carrying or bonding, the materials thereof are not specifically limited in the present disclosure. In some embodiments, the temporary substrate 111 may be formed of silicon (Si), sapphire, glass, or other suitable materials, and the bonding layer 109 may be formed of, for example, resin. After the LLO process, in some embodiments, as shown in FIG. 5, the second semiconductor layer 104 may include an uneven surface 104S1. The uneven surface 104S1 is formed by removing the native substrate 107 with patterned surface, for example, a patterned sapphire substrate (PSS). In some embodiments, the uneven surface 104S1 comprising a plurality of dimples.

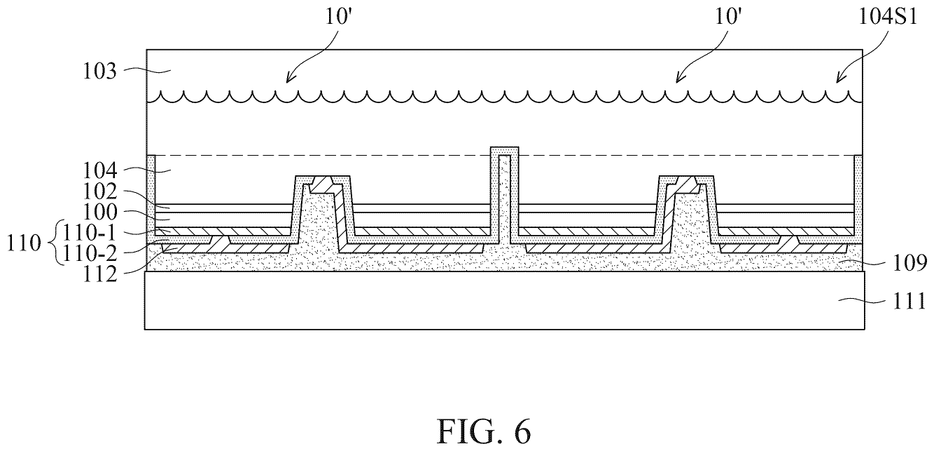

Next, referring to FIG. 6, a first photoresist layer 103 is formed onto the second semiconductor layer 104 to cover the uneven surface 104S1, and the first photoresist layer 103 may have a similar etch selectivity to that of the second semiconductor layer 104. The first photoresist layer 103 may be formed by any suitable process, such as a spin coating process. In some embodiments, the first photoresist layer 103 fills the dimples of the uneven surface 104S1.

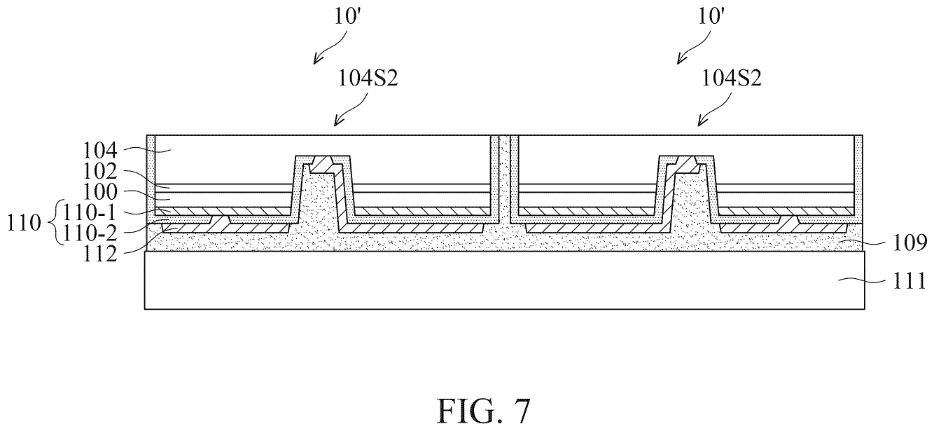

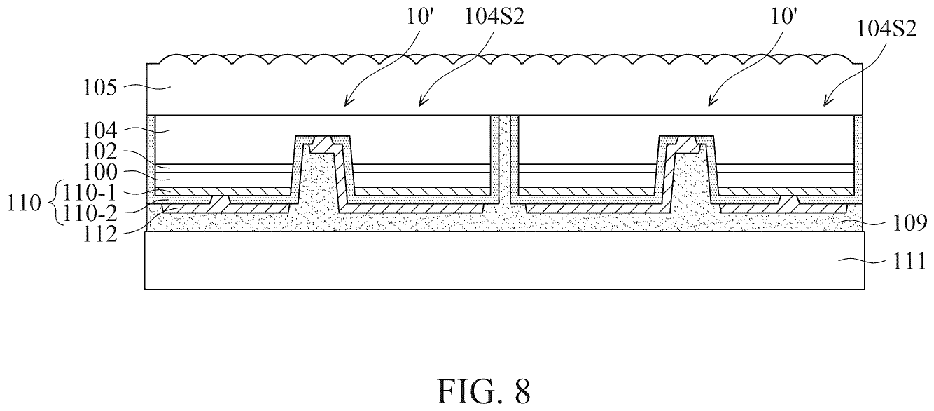

Next, referring to FIG. 7, a first etch process is performed on the LED chips 10′ to remove the first photoresist layer 103 and the uneven surface 104S1 of the second semiconductor layer 104, thereby forming a flat surface 104S2 of the second semiconductor layer 104 of the LED chip 10′. Since the uneven surface 104S1 is removed, there is no more dimple exist, and the light emitted from the active layer 102 will not be diffracted by the dimples, which is beneficial to narrow the light-emission angle. The first photoresist layer 103 and the uneven surface 104S1 may be removed by any suitable etch process, for example, dry etch (such as reactive ion etch (RIE)), neutral beam etch (NBE), combinations thereof, or the like. In some embodiments, the etch process may be a dry etch process, and the ratio of the etch rate of the first photoresist layer 103 to that of the second semiconductor layer 104 is 1:1. Specifically, the etch process may be a dry etch process using chlorine gas or boron trichloride as an etchant, and be conducted under the condition that the second semiconductor layer 104 is blanketly covered by the first photoresist layer 103 to dry etch the first photoresist layer 103 and the second semiconductor layer 104. In some embodiments, after the first etch process, the second semiconductor layers 104 of the LED chips 10′ are separated. In other words, the LED chips 10′ are physically separated from each other, and each of the LED chips 10′ has one flat surface 104S2 of the second semiconductor layer 104. Next, referring to FIG. 8, a second photoresist layer 105 is formed onto the flat surface 104S2 of the second semiconductor layer 104. The first photoresist layer 103 and the second photoresist layer 105 may be formed of the same or different materials, and the second photoresist layer 105 may be formed by any suitable process, such as spin coating process. As shown in FIG. 8, after forming the second photoresist layer 105, any suitable photolithography process may be used to pattern the second photoresist layer 105 to form a convex lens structure. For example, patterning the second photoresist layer 105 may be as follows: exposing the second photoresist layer 105 according to a patterned mask (not shown), followed by a post-exposure baking, photoresist development, washing, drying (spin-drying and/or hard baking), other suitable photolithography techniques, and/or combinations thereof. In detail, a photolithography process may be firstly performed on the second photoresist layer 105 when the second photoresist layer 105 is formed onto the second semiconductor layer 104, and then performing a hard baking until the second photoresist layer 105 has micro-collapses, thereby patterning the second photoresist layer 105 to form a convex lens structure. In some embodiments, the second photoresist layer 105 covers the individual LED chips 10′, that is, the second photoresist layer 105 formed onto the flat surfaces 104S2 of the second semiconductor layers 104 of the LED chips 10′.

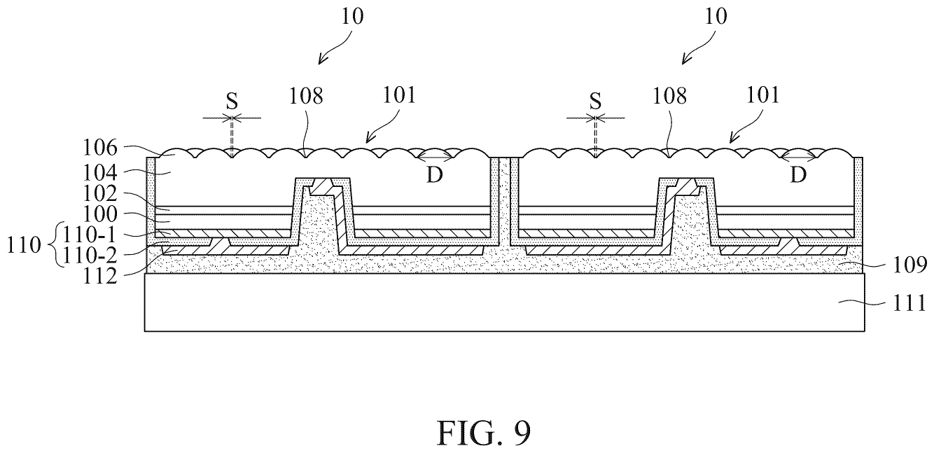

Finally, referring to FIG. 9, a second etch process is performed on the LED chips 10′ to transfer the pattern of the convex lens structure of the second photoresist layer 105 to the second semiconductor layer 104, thereby obtaining a plurality of light-emitting elements 10 each has a plurality of microlenses 106 integrally formed on the second semiconductor layer 104. Specifically, the second photoresist layer 105 and the flat surfaces 104S2 of the second semiconductor layers 104 are gradually and conformally etched (removed) in sequence according to the pattern of the convex lens structure of the second photoresist layer 105 until the microlenses 106 are formed. The second photoresist layer 105 may be removed and the second semiconductor layer 104 may be patterned by any suitable etch process, for example, dry etch (such as reactive ion etching (RIE), neutral beam etch (NBE)), combinations thereof, or the like. In some embodiments, the etch process is a dry etch process. Specifically, the etch process may be a dry etch process using chlorine gas or boron trichloride as an etchant, and be conducted under the condition that the etch depth is controlled in 0.5 to 1 μm, to sequentially dry etch the second photoresist layer 105 and the second semiconductor layer 104, thereby achieving the transfer of the pattern.

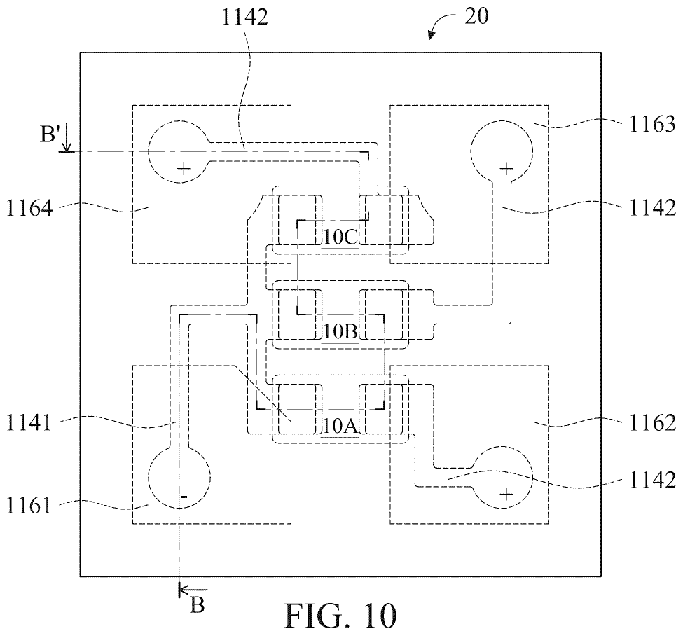

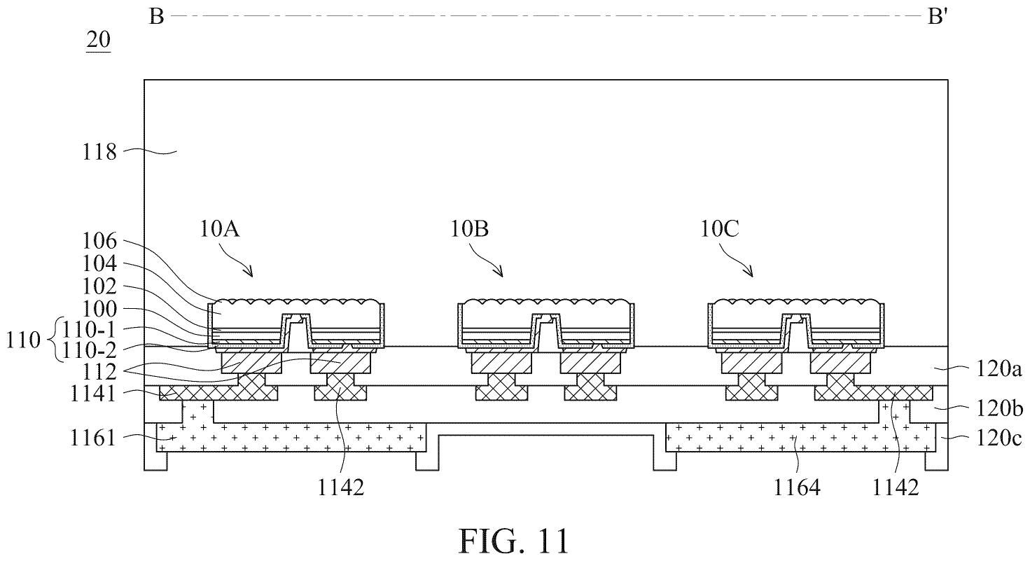

The present disclosure also provides a light-emitting element package structure 20, and FIG. 10 is a top view of the light-emitting element package structure 20 in accordance with some embodiments of the present disclosure. As shown in FIG. 10, the light-emitting element package structure 20 has three light-emitting elements 10A, 10B, and 10C disposed alongside, and four metal pads 1161,1162,1163, and 1164. The metal pad 1161 is electrically connected to the light-emitting elements 10A, 10B, and 10C, and the metal pads 1162, 1163 and 1164 are electrically connected to the corresponding one of the light-emitting elements 10A, 10B, and 10C respectively. Specifically, one electrode 112 (such as the cathode shown in FIG. 11) of each of the light-emitting elements 10A, 10, and 10C is electrically connected to the metal pad 1161 by one redistribution layer 1141, and another electrode 112 (such as the anode, shown in FIG. 11) of each of the light-emitting elements 10A, 10B, and 10C is electrically connected respectively to the corresponding metal pads 1162, 1163 and 1164 by three different redistribution layers 1142. That is, the light-emitting elements 10A, 10B, and 10C in the light-emitting element package structure 20 are electrically connected to each other by one common-cathode (i.e. the metal pad 1161). In other embodiments, the micro light-emitting elements 10A, 10B, and 10C in the light-emitting element package structure 20 may be electrically connected to each other by one common-anode. Note that the structure shown in FIG. 10 is merely an example, and the present disclosure is not limited thereto. In other embodiments, the light-emitting element package structure 20 may have more than three or less than three light-emitting elements, and the light-emitting elements may be respectively connected to different metal pads.

Next, refer to FIG. 11, which is a cross-sectional view of a light-emitting element package structure 20 taken along line B-B′ of FIG. 10 in accordance with some embodiments of the present disclosure. As shown in FIG. 11, the light-emitting element package structure 20 has a plurality of metal pads 1161, 1162,1163, and 1164, three light-emitting elements 10A, 10B, and 10C disposed on the metal pads 1161, 1162,1163, and 1164 side by side, and an encapsulation layer 118 encapsulating the light-emitting elements 10A, 10B, and 10C. Each of the light-emitting elements 10A, 10B, and 10C has a first semiconductor layer 100, an active layer 102, a second semiconductor layer 104, and two electrodes 112, and the top surface of the second semiconductor layer 104 is disposed with a convex lens structure formed by a plurality of microlenses 106 for converging the emission light from the active layer 102. The metal pads 1161, 1162,1163, and 1164 are respectively electrically connected to the first semiconductor layer 100 and the second semiconductor layer 104 of each of the light-emitting elements 10A, 10B, and 10C by the redistribution layers 1141 and 1142. It should be noted that although the flat region 108 and the spacing S between the microlenses 106 are not shown in the cross-sectional view in FIG. 11, the light-emitting elements 10A, 10B, and 10C may still have the flat region 108 and the spacing S described herein in another cross-sectional view. In some embodiments, as shown in FIG. 11, each of the light-emitting elements 10A, 10B, and 10C may have a reflection layer 110 respectively. The materials and structures of the first semiconductor layer 100, the active layer 102, the second semiconductor layer 104, the microlens 106, the electrode 112, and the reflection layer 110 have been described above regarding the light-emitting element 10, and thus will not be repeated herein. By making the light-emitting element package structure 20 have the light-emitting elements 10A, 10B, and 10C with the convex lens structure, each of the light-emitting elements 10A, 10B, and 10C can emit light with narrow light-emission angle due to the converging effect of the convex lens, thereby avoiding color shift caused by large light-emission angle. In some embodiments, the light-emission angle of the light-emitting element package structure 20 may be about 110 degrees to about 140 degrees, for example, about 120 degrees to about 130 degrees, about 110 degrees to about 120 degrees.

In some embodiments, the light-emitting elements 10A, 10B, and 10C in the light-emitting element package structure 20 may be a combination of gallium arsenide (GaAs) light-emitting elements and gallium nitride (GaN) light-emitting elements. For example, the light-emitting element 10A may be a gallium arsenide (GaAs) light-emitting element for emitting red light, and the light-emitting elements 10B and 10C may be gallium nitride light-emitting elements for emitting green light and blue light respectively, but the present disclosure is not limited thereto.

In some embodiments, the encapsulation layer 118 may comprise epoxy, silicone, or polyurethane, but the present disclosure is not limited thereto. In some embodiments, the light-emitting element package structure 20 may include insulating layers 120a, 120b, and 120c filled between the electrodes 112, the redistribution layers 1141 and 1142, and the metal pads 1161, 1162, 1163, and 1164 to avoid undesired electrical connections. In some embodiments, the insulating layers 120a, 120b, and 120c may include epoxy resin, polyimide (PI), polybenzoxazole (PBO), silicone resin, silicon oxide, silicon nitride, or combinations thereof, but the present disclosure is not limited thereto. In some embodiments, the materials of the insulating layers 120a, 120b, and 120c may be different from the material of the encapsulation layer 118. In other embodiments, the material of the insulating layers 120a, 120b, and 120c may be similar to the material of the encapsulation layer 118.

According to the embodiments provided in the present disclosure, the light-emitting element having a convex lens structure integrally formed with and have the same material as the underlying semiconductor layer can achieve the effect of narrowing the light-emission angle through the converging effect of the convex lens, thereby converging the emission light of light-emitting element (such as, micro-LED) and enhancing the effect of forward light emission. Furthermore, because the light-emission angle of each of the light-emitting elements of the present disclosure are smaller, the package structure including the abovementioned light-emitting elements can avoid color shift caused by too large light-emission angle.

The foregoing outlines several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A light-emitting element, comprising:
a first semiconductor layer;
an active layer disposed on the first semiconductor layer;
a second semiconductor layer disposed on the active layer; and
a convex lens structure disposed on the second semiconductor layer comprises a plurality of microlenses, wherein the microlenses and the second semiconductor layer are integrally formed and have the same material, wherein a radius of curvature of one of the microlenses is 0.2 μm to 5.0 μm, and a light-emission angle of the light-emitting element is 100° to 110°.

2. The light-emitting element as claimed in claim 1, wherein a diameter of one of the microlenses is 1.0 μm to 4.0 μm, and a height of one of the microlenses is 0.5 μm to 5.0 μm.

3. The light-emitting element as claimed in claim 1, wherein an arrangement of the microlenses is hexagonal close-packed.

4. The light-emitting element as claimed in claim 1, wherein a spacing between adjacent two of the microlenses is less than 2 μm.

5. The light-emitting element as claimed in claim 1, further comprising:
a first electrode and a second electrode disposed on a side of the first semiconductor layer opposite to the active layer, wherein the first electrode and the second electrode are separated from each other and electrically connected to the first semiconductor layer and the second semiconductor layer respectively.

6. The light-emitting element as claimed in claim 5, further comprising: an insulating layer disposed between the first semiconductor layer and the first electrode, and between the first semiconductor layer and the second electrode.

7. The light-emitting element as claimed in claim 6, wherein the insulating layer is a distributed Bragg reflector (DBR).

8. The light-emitting element as claimed in claim 6, wherein the first electrode and the second electrode penetrate the insulating layer to electrically connect to the first semiconductor layer and the second semiconductor layer respectively.

9. A package structure, comprising:
a first metal pad and a plurality of second metal pads, the second metal pads are separated from each other, and the first metal pad is separated from each of the second metal pads;
a plurality of light-emitting elements disposed on the first metal pad and the second metal pads, each of the light-emitting elements has a light-emitting surface with a convex lens structure; and
an encapsulation layer encapsulating the light-emitting elements;
wherein the first metal pad is electrically connected to at least two of the light-emitting elements, and the second metal pads are electrically connected to the corresponding one of the light-emitting elements respectively.

10. The package structure as claimed in claim 9, each of the light-emitting elements comprising:
a first semiconductor layer, an active layer and a second semiconductor layer stacked in sequence, wherein the first semiconductor layer and the second semiconductor layer of each of the light-emitting elements are electrically connected to the first metal pad and the corresponding one of the second metal pads respectively.

11. The package structure as claimed in claim 10, one of the light-emitting elements further comprising:
a distributed Bragg reflector (DBR) disposed between the first semiconductor layer and the first metal pad, and between the first semiconductor layer and the second metal pad.

12. The package structure as claimed in claim 9, wherein at least two of the light-emitting elements emit lights with different color.

13. The package structure as claimed in claim 9, wherein one of the light-emitting elements is a gallium arsenide (GaAs) light-emitting element and the other one of the light-emitting elements is a gallium nitride (GaN) light-emitting element.

14. The package structure as claimed in claim 9, wherein a light-emission angle of the package structure is 110° to 140°.

15. A manufacturing method of a light-emitting element, comprising:
providing a substrate having a plurality of light-emitting diode chips disposed thereon, wherein each of the light-emitting diode chips comprises a first semiconductor layer, an active layer, and a second semiconductor layer stacked in sequence while the second semiconductor layer positioned between the active layer and the substrate;
removing the substrate from the light-emitting diode chips to form a plurality of uneven surfaces of the second semiconductor layers;
removing the uneven surfaces of the second semiconductor layers to form a plurality of flat surfaces; and
patterning the flat surfaces of the second semiconductor layers to form convex lens structures.

16. The manufacturing method of a light-emitting element as claimed in claim 15, wherein removing the uneven surfaces of the second semiconductor layers comprises:
forming a first photoresist layer on the second semiconductor layers to cover the uneven surfaces; and
performing a first etch process to remove the first photoresist layer and the uneven surfaces to form the flat surfaces of the second semiconductor layers.

17. The manufacturing method of a light-emitting element as claimed in claim 15, wherein patterning the flat surfaces of the second semiconductor layers comprises:
forming a second photoresist layer covering the flat surfaces of the second semiconductor layers;
patterning the second photoresist layer to form a pattern of a convex lens structure; and
performing a second etch process to pattern the flat surfaces of the second semiconductor layers and form the convex lens structures.

18. The manufacturing method of a light-emitting element as claimed in claim 15, wherein before removing the uneven surfaces of the second semiconductor layers, the second semiconductor layers of the light-emitting diode chips are connected to each other.

19. The manufacturing method of a light-emitting element as claimed in claim 18, wherein after removing the uneven surfaces of the second semiconductor layers, the second semiconductor layers of the light-emitting diode chips are separated from each other to form a plurality of individual light-emitting diode chips.

20. The manufacturing method of a light-emitting element as claimed in claim 16, wherein a ratio of an etch rate of the first photoresist layer to that of the second semiconductor layers is 1:1.
